(19) United States
(12) Patent Application Publication
(10) Pub. No.: US 2008/0203469 A1
(43) Pub. Date: Aug. 28, 2008

(54) INTEGRATED CIRCUIT INCLUDING AN ARRAY OF MEMORY CELLS HAVING DUAL GATE TRANSISTORS

(75) Inventor: Ulrike Gruening-von Schwerin, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/680,336

(22) Filed: Feb. 28, 2007

(51) Int. Cl. H01L 27/088; H01L 21/336

(52) U.S. Cl. 257/327; 257/365; 438/283; 257/E21.255; 257/E27.06; 257/5

(57) ABSTRACT

An integrated circuit including an array of memory cells having dual gate transistors with curved current flow, and method for operation and fabrication is disclosed. In one embodiment, in a substrate an array of transistors is formed for selecting one of a plurality of memory cells by selecting a pair of adjacent word lines and a bit line. For minimizing the area of a memory cell and reducing complexity in production an array of dual gate transistors having a curved current flow is disclosed, wherein a small portion of a current is allowed to flow through adjacent memory cells.

### BACKGROUND

The invention relates to an integrated circuit having an array of selection transistors for selecting one of a plurality of resistively switching memory cells, a corresponding method of operation and a fabrication method.

Resistively switching memory cells are based on a reversible change of the resistance of an active or switching active material in the cell and wherein the change is induced by applying an appropriate voltage or current to the switching active material. Examples of resistively switching memory cells are phase change (PC) memories employing chalcogenides, magneto resistive RAM (MRAM), conducting bridge (CB) memories using metal-doped chalcogenides, transition metal oxide resistive change RAM (TMO RRAM) employing materials like NiOₓ, TiOₓ, HfOₓ, ZrOₓ or perovskite oxides.

In phase change memories the change in resistance is based on the amorphous-crystalline phase transition of the phase change material being the switching active material. The phase change materials include the family of chalcogenide compounds, for example such as the commonly used GeSbTe or AgInSbTe. As the resistance of the switching active material in the crystalline state differs significantly from the resistance of the material in the amorphous state, a logic bit can be assigned to a cell, wherein a first logical state of the bit can be assigned to the conducting/less resistive state and the second logical state of the bit can be assigned to the less conducting/resistive state of the phase change memory cell. Reading the cell, i.e. by determining its resistance, can retrieve the value of the bit. For writing a bit value assigned to the conducting/less resistive state to the cell, i.e. to transform the phase change material from amorphous to crystalline, a current pulse is sent through the switching active material to heat the material over its crystallization temperature thus lowering its resistance. For resetting a phase change memory cell to the less conducting/more resistive state a comparatively strong current pulse is sent through the phase change material for heating and causing the switching material to melt, which is subsequently forced into the amorphous state by quench cooling the material. A further description of these memory cells can be found for example in S. J. Ahn, “Highly Manufacturable High Density Phase Change Memory of 64 MB and Beyond”, IEDM 2004, H. Horii et al “A novel cell technology using N-doped GeSbTe films for phase change RAM”, VLSI, 2003, Y. N. Hwang et al “Full integration and reliability evaluation of phase-change RAM based on 0.24 um-CMOS technologies”, VLSI, 2003, S. Lai et al “OUM—a 180 nm non-volatile memory cell element technology for stand alone and embedded applications”, IEDM 2001, or Y. H. Ha et al “An edge contact cell type cell for phase change RAM featuring very low power consumption,” VLSI, 2003.

In CBRAM technology solid-state ionic devices composed of a metal-doped glasses are used as switching active material. The memory effect is based on polarity dependant switching at small bias and current due to the electrodeposition of metal in the glassy electrolyte. Low voltage operation, high on/off ratios and considerable scaling potential are the benefits of CBRAMs making this technology promising for future volatile as well as non-volatile memory applications.

Solid-state ionic memory utilizes solid-state electrochemistry at the nanoscale in certain materials, generally referred to as solid electrolytes. These memory elements are composed of a thin film of silver doped chalcogenide or oxide glass sandwiched between a silver anode and an inert cathode. Under the influence of an electric field the electron current from the cathode reduces an equivalent number of Ag-ions as injected from the anode and a metal-rich electrodeposit is thereby formed in the electrolyte. The magnitude and the duration of the ion current determines the amount of Ag deposited and hence the conductivity of the pathway. The electrodeposit is electrically neutral and stable and the formation process can be reversed by applying a bias with opposite polarity thus increasing resistivity until the high value of the solid electrolyte is reached. This resistive switching can be used similarly as explicated above for storing one bit.

The TMO RRAM memory concept is based on a (normally insulating) oxidic film sandwiched between metal electrodes, commonly referred to as top and bottom electrode. Upon sweeping or pulsing the device undergoes a large field induced resistance change of about 1 to 5 orders of magnitude, depending on the specific properties of the device. Similarly to PCRAM, MRAM or CBRAM a cell can be read by applying a small voltage and sensing the current through the cell, wherein “small” means a smaller amplitude in comparison to the threshold voltage for writing the cell. Writing and resetting a cell can be caused by applying a positive or negative voltage pulse to the cell.

In a memory device having a plurality of memory cells, the cells usually are arranged in a ITIR order, that is one transistor is assigned to one resistively switching memory cell for selecting the cell. The most common arrangement is to couple one electrode of the memory cell to a bitline and the residual electrode to the drain of the selection transistor, while the source of the selection transistor is coupled to a reference voltage, referred to as ground. As the gates of selection transistors are coupled to wordlines, which basically run orthogonal to the bitlines, a memory cell can be selected by selecting the corresponding pair of bitline and wordline.

For being cost competitive an ever-challenging problem is to reduce the size of memory cells in order to achieve a high density of a memory cell array, while at the same time the selection transistors, also called array transistors, must be able to supply sufficient current for switching the cells.

Various concepts have been proposed for reducing the size of memory cells. For example for PCRAM cell planar or FINFET transistors have been proposed. However these layouts are limited to 6F2 cells sizes, wherein F denotes the minimum feature size defined by conventional manufacturing methods. Yet vertical transistor structures allow a further reduction of the cell size.

US20050001257A1 describes a transistor array having vertical transistors featuring spacer wordlines and a buried plate electrode, which can be applied to resistively switching memory cells.

However conventional vertical transistor concepts have a transistor body isolated from the wafer substrate in common. Hence these transistors are not at all or only weakly coupled to external voltages. Furthermore the proposed buried ground plate is to be formed and coupled to an external voltage, for example ground, which causes additional processing of the substrates and/or non-standard substrate wafers.

DE10361695B3 discloses a fin gate transistor (CFET) having a curved channel and its implementation in a DRAM memory array, wherein the disclosed CFET prevents leakage currents.

For these and other reasons, there is a need for the present invention.

### SUMMARY

One embodiment provides an integrated circuit including an array of memory cells having dual gate transistors with curved current flow, and method for operation and fabrication. In one embodiment, in a substrate an array of transistors is formed for selecting one of a plurality of memory cells by selecting a pair of adjacent word lines and a bit line. For minimizing the area of a memory cell and reducing complexity in production an array of dual gate transistors having a curved current flow is disclosed, wherein a small portion of a current is allowed to flow through adjacent memory cells.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic circuit diagram of two memory cells exemplifying an array of several memory cells in a first embodiment.

FIGS. 2A, B, C illustrate cross sections and a top view of a first embodiment with alternating bit lines and ground lines.

FIG. 3 illustrates a schematic circuit diagram of two memory cells representing an array of several memory cells of a second embodiment.

FIGS. 4A, B, C illustrate cross sections through the second embodiment having a checkerboard like layout and a corresponding top view.

FIG. 5A, B, C illustrate cross sections of a third embodiment and a corresponding top view on the layout.

FIG. 5D a circuit exemplifying resistances in the layout.

FIG. 6A, B, C illustrate cross sections through a fourth embodiment wherein a plurality of bit lines per ground line is arranged and a corresponding top view on the layout.

FIG. 7A-D illustrate cross sectional views of the fabrication process in different stages.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The invention relates to an integrated circuit having an array of selection transistors for selecting one of a plurality of resistively switching memory cells, a corresponding method of operation and a fabrication method.

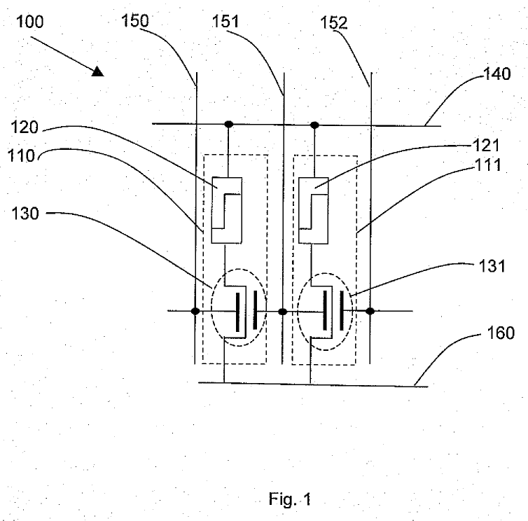

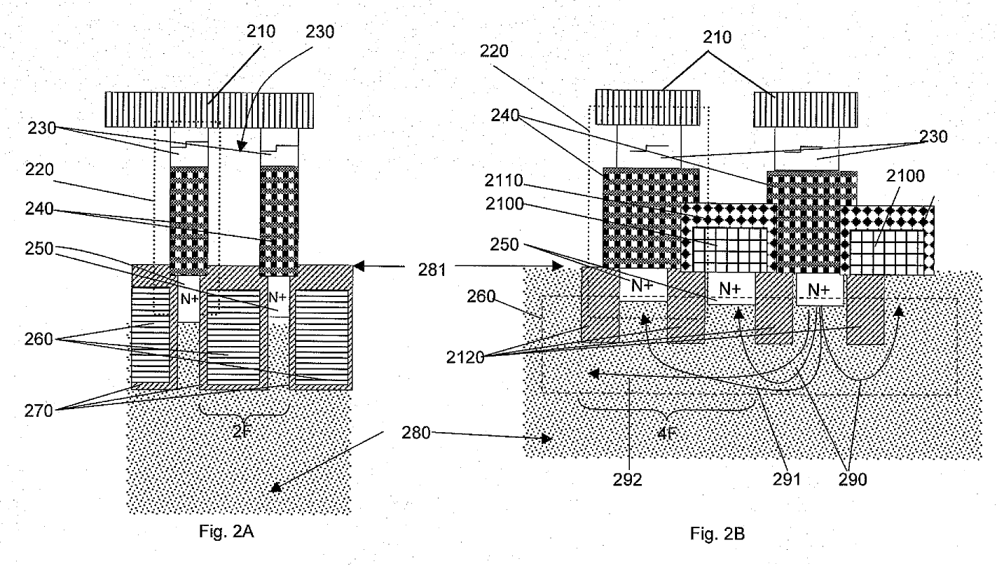

FIG. 1 illustrates an electrical circuit 100. A first and a second resistive memory cell 110, 111, each surrounded by a dotted line, exemplify a plurality of identical memory cells arranged in an array of memory cells.

Each memory cell 110, 111 includes a memory element 120, 121 and one selection transistor 130, 131.

It is apparent to those skilled in the art that in this drawing and throughout the invention the memory element can be any of the afore described types of resistively switching memory element, for example a volume of phase change material of a PCRAM memory cell or a volume of suitable material of a conducting bridge CBRAM memory cell or of an MRAM cell. In the embodiments described hereinafter a PCRAM memory cell having a volume of phase change material, wherein the volume of phase change material is denoted as switching active material, exemplifies any resistively switching memory cell.

The memory elements 120, 121 are coupled to a bitline 140 with their one end and to a first source/drain region of the selection transistor 130, 131 of the corresponding memory cell with their residual end.

As indicated in the drawing the selection transistors 130, 131 are fully depleted, double gate transistors, wherein the two gates of each transistor are coupled to different wordlines. For example the gate on the left hand side of selection transistor 130 is coupled to a first word line 150 and the gate on the right hand side of the selection transistor 130 is coupled to a second word line 151. Similarly the gate on the left hand side of selection transistor 131 is coupled to word line 151 and the gate on the right hand side is coupled to word line 152.

As noted above a first source/drain region of each selection transistor 130, 131 is coupled to the memory element 120, 121 of the corresponding cell. The second source/drain region of each selection transistor is coupled to a reference line 160 providing a reference potential, which is assumed to be ground in all described embodiments.

The selection transistors are designed such that they are operated—in this and all subsequently described embodiments—as double gate transistors in fully depleted mode in its on-state, if both gates of a selection transistor are raised high. In case that one gate of a selection transistor is raised high while the other is kept low, then the transistor is operated as a single gate transistor having a backgate and the threshold voltage of the transistor is raised. Accordingly a transistor is not fully turned on, hence showing a considerable smaller current flow. In case that both gates are kept low, then the transistor is completely switched off allowing only a negligible current flow.

For writing a logic value to a cell, i.e. to change the resistance of the memory element of the cell thus setting or resetting the cell, both gates of the selection transistor have to be raised to turn the transistor on, and the bitline must be raised to writing voltage. For example in order to set/reset cell 110 the voltage of wordlines 150 and 151 and the voltage of bitline 140 must be raised, so that a write current will flow from bitline 140 through memory element 120 and selection transistor 130 to ground line 160.

Due to the raised voltage of wordline 151 the left hand gate of selection transistor 131 is also raised high. However, as explicated afore, the voltage at the gate on the right hand side of selection transistor 131 is kept low. Hence selection transistor 131 is not turned on, or at least not fully turned on. The parasitic current flowing through transistor 131 and also through the memory element 121 of memory cell 111 is below the switching threshold, thus leaving the state of cell 111 unmodified.

For reading a cell, that is for determining the resistance value of its memory element, the corresponding transistor is turned on by raising the gate voltages, a voltage is applied to the bitline and the amplitude of the current flowing through the memory element is sensed. As a side effect of turning on for example transistor 130 of memory cell 110 one gate of a selection transistor of an adjacent memory cell is raised, in this example the gate on the left hand side of adjacent cell 111. As cell 111 is coupled to the same bitline 140 an undesired, parasitic current will flow through memory element 121 of the adjacent memory cell, which falsifies the accurate sensing of the current flowing through cell 110. In a worst-case scenario a cell 110 to be sensed is in high resistance state while adjacent memory cells are in a low resistance state. However if the selection transistors are designed such that for sensing cell 110 the transistors of adjacent cells 111 operate in the subthreshold regime, then the transistor resistance can be increased by at least 1-2 orders of magnitude and the signal margin is expected to be large enough.

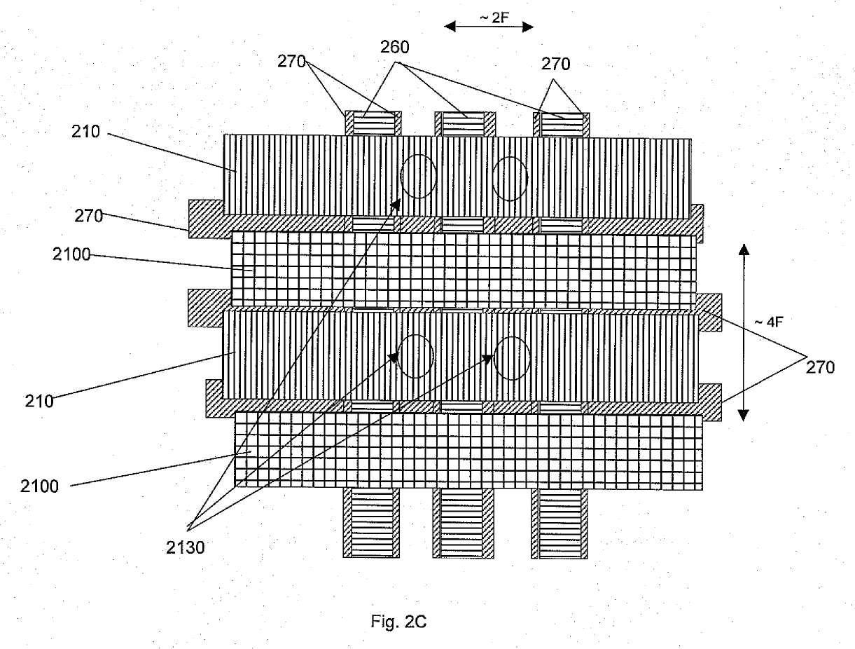

One embodiment, is schematically illustrated in FIGS. 2A, 2B. FIG. 2A illustrates a cross section through a dual gate memory cell, encircled by dotted line 220, exemplifying a plurality of cells arranged in an array of cells, and wherein the cut line is perpendicular to a bitline 210.

It is apparent for those skilled in the art that these and all following figures schematically illustrate the important elements and that any empty space between functional elements is filled with an appropriate insulating material. For example the space denoted by reference numeral 230 is filled with silicon oxide.

The illustrated memory cell includes a volume of switching active material 230, which maps to a memory element of FIG. 1, and which is coupled to bitline 210 at its top. The switching active material 230 couples a bottom electrode contact 240, which in turn connects to the N+ implanted drain region 250 of a selection transistor. The selection transistor includes two gate electrodes, which are formed by wordlines 260 formed of P-doped silicon produced by appropriate implanting of the original wafer material and embedded in an appropriate insulation forming the gate oxide 270. The wordlines 260 and the embedding insulating material 270 are formed in word line trenches located below the original surface of the wafer/substrate 280 and are thus buried. The original surface of the wafer is denoted by arrow 281.

The pair of gate electrodes of a transistor is thus formed by wordlines 260, which in this view run into the paper plane of the drawing. Hence the conducting channel of a transistor is induced in the substrate material between a pair of word lines and extends along the word lines and is not limited to the area of the source/drain region of the transistor.

FIG. 2B illustrates a cross section through the cells, wherein the cut line is perpendicular to that of FIG. 2A and through a volume of switching active material 230. Accordingly the word lines 260, indicated by the dotted square, are located in front of and behind the paper plane of the drawing.

When turning on a transistor into its fully conducting state a current originating from bitline 210 will flow through the switching active material 230, the bottom electrode 240 and the source/drain 260 and will then enter the induced channel. As indicated by arrows 290 most of the current will leave the channel through the closest source/drain regions 260 coupled to ground lines 2100. The ground lines 2100 can be formed of any suitable material, for example a metal. In this view ground lines 2100 run parallel to bit lines and are embedded in a suitable insulating material 2110 such as SiN. However a smaller amount of the current emerging from the operated cell will leave the conducting channel of the transistor, which as explicated above extends along the length of the word lines, through an adjacent source/drain region coupled to an adjacent memory element and thus through an adjacent memory cell as indicated by arrow 291. Although in this exemplifying figure arrow 291 is directed to the left it is apparent that for reasons of symmetry a similar amount of current will flow to the right hand side.

Furthermore another, still smaller amount of current will travel further along the conducting channel as denoted by arrow 292 and will leave via another ground line or another memory cell, wherein the amount of current becomes smaller with increasing distance from the operated memory cell.

As explained above the current portions 291, 292 traveling along the conducting channel and leaving it through any memory cell are parasitic for these cells. However they do not affect the proper operation of the memory cells as long as their amplitude is below the threshold of switching a cell.

For preventing the induction of a conducting channel below the word lines a thicker layer of insulating material can be optionally applied to the bottom of the word line trenches, such that there is no formation of a conductive channel in the p-doped substrate at the bottom of the word line trenches. For example, the thickness of the gate oxide deposited at the bottom of the word lines can be at least twice the thickness of the gate oxide at the sidewalls. Furthermore in order to prevent a conducting channel in an adjacent transistor channel, the voltage of word lines parallel to those needed for selecting a memory cell can be biased negative so that a current flow into memory cells located behind or in front of the raised word lines is prevented. In this way a current through cells located in front of or behind the paper plane of the drawing can be prevented or at least considerably lowered.

In order to prevent a short-circuit between a source/drain at a ground line 2100 and a source/drain at a bottom electrode 240 a groove 2120 lined with a suitable insulation material is arranged between the source/drain regions, which forces the current to flow in a curve around it as denoted by curved arrows 290. In this way the selection transistors in this and the following embodiments are curved FET (CFET), as the current flow thus is curved between its source and drain.

Although the figure is not drawn to scale the width of a source/drain region of a transistor, as denoted by the curved brackets, and of an insulation groove each is 1 F, so that the size of one memory cell is 2 F×4 F=8 F².

In one embodiment, bit lines and ground lines are arranged alternating.

FIG. 2c illustrates a top view on the layout of the memory cells. Bit lines 210 are the topmost elements in this illustration. The bit lines cover the volumes of switching active materials and their corresponding bottom contacts. The bottom contacts are coupled to the active areas of selection transistors. Circles 2130 indicate the location of the active areas. As explicated above word lines 260 serve as gate electrodes for the transistors. The gate electrodes are insulated from the active areas by a gate dielectric 270. Insulating material also lines the insulation groove between source/drain regions of transistors thus forcing the current to flow curved. In this drawing current emerging from bit lines into volumes of switching material—not illustrated—and conducted via bottom electrode contacts—not illustrated—to the active areas flows vertically, then curved and more or less parallel to the original surface of the substrate to the source/drain regions located below ground lines. The current leaves the conducting channel via ground lines 2100, wherein most of the current will leave the channel at the next ground line, and smaller amplitudes will leave at following ground lines.

In this and all subsequently described embodiments the original surface of the wafer or chip serves as a reference plane for describing the position of elements as created in the described processes. However as is apparent to those skilled in the art the essential constituents of the memory cells can be created above the original surface of the wafer for example by epitaxially growing silicon on the wafer surface. The grown material may then serve as a basis for creating the essential constituents. Insofar the surface of the grown material serves as a substrate equivalent to the original surface of the wafer/chip. Accordingly a plane parallel to the surface of the substrate, which may be the original wafer/chip or silicon grown thereon, serves as a reference plane.

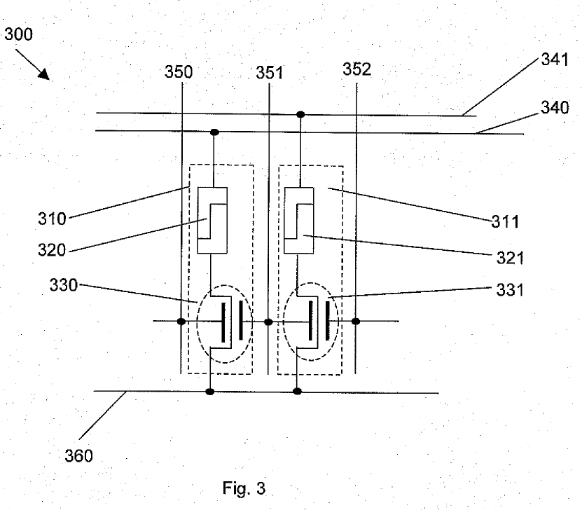

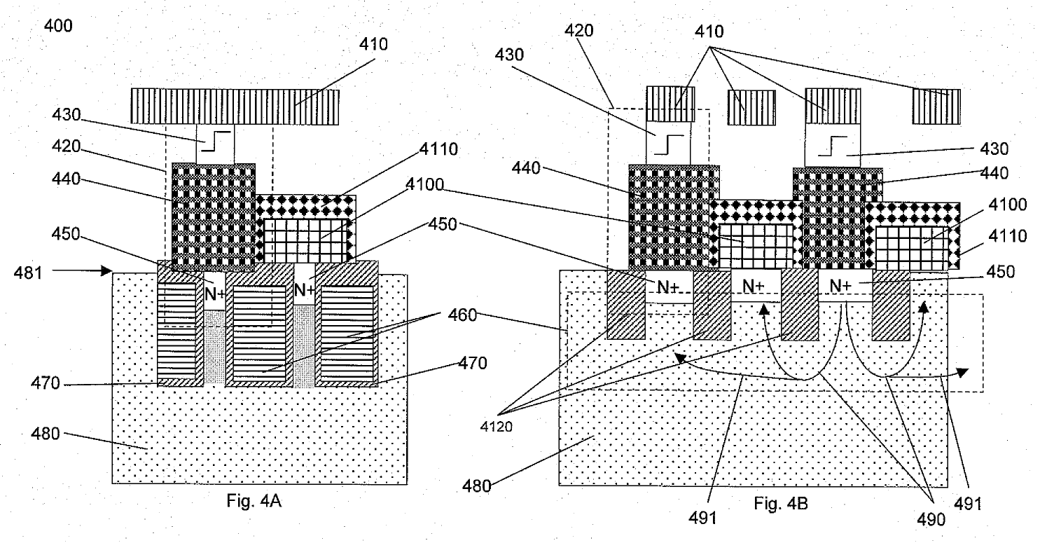

The circuit 300 of FIG. 3 illustrates a second embodiment of the invention illustrating a checkerboard like arrangement of memory cells. A first and a second, adjacent memory cell 310, 311, each encircled by a dotted line each comprise a memory element 320, 321 and a dual gate CFET transistor 330, 331 respectively. The transistors are each coupled to the memory elements 320, 321 with their one source/drain and to a ground electrode 360 with their residual source/drain region. The word lines 350, 351, 352 form the gate electrodes of the transistors 330, 331. Similar to the first embodiment each word line forms one gate electrode of a first pair of word lines and one word line of a second pair of word lines, the pairs of word lines thus sharing one word line.

The second embodiment differs from the first in that the memory cells are coupled to different bit lines, i.e. cell 310 is coupled to bit line 340 whereas cell 311 couples to bit line 341. In comparison to the first embodiment these cells are less prone to interference of parasitic currents. For example when raising the voltage of bit line 340 and of word lines 350 and 351 in order to read or write memory cell 310 the voltage of the left hand gate of transistor 331 is raised also. However as memory cell 311 is coupled to another bit line, i.e. bit line 341, there will be no or at least a significantly smaller parasitic current flowing through memory cell 311, because the voltage of bit line 311 is not raised.

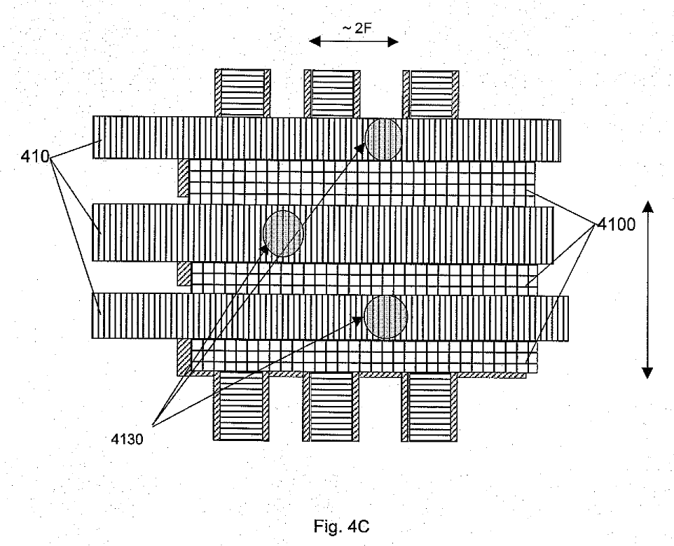

FIG. 4A illustrates a cross section through a memory cell layout of the second embodiment having similarities to the first embodiment, wherein the cut line runs parallel to and through a bitline 410. A memory cell 420, encircled by the dotted line, couples to a bit line 410 and includes a volume of switching active material 430 as memory element. The memory element is on its top side coupled to bit line 410 and via a bottom electrode contact 440 coupled to a N+ doped source/drain region of a selection transistor. Wordlines 460 run perpendicular to the bitlines, i.e. in this view into the paper plane of the drawing. The wordlines 460 are embedded in insulating material 470 and form the gates of the transistors. The insulating material 470 accordingly forms the gate oxide. Reference sign 480 denotes the original wafer/substrate material and 481 denotes the surface of the original wafer/substrate. As illustrated in the drawing the word lines 460 are arranged below the surface of the original substrate, thus the wordlines are buried below the original surface plane of the substrate.

Similar as described for the first embodiment for operating a memory cell, that is reading or writing, the voltage of both word lines 460 is raised thus inducting a conducting channel running between the word lines.

Note that as an alternative to the illustrated buried wordlines a conventional word line stack—not illustrated—having a first layer of conducting material such as poly silicon and another layer of a metal such as tungsten, can be used, wherein the word line stack is located at least partially above the surface of the original wafer 481.

FIG. 4B illustrates a cross section through the second embodiment, wherein the cut line is perpendicular to the bit lines 410. Similar to the previous figures the word lines are located in front and behind the paper plane of the drawing as the cut line lies between these. For reading or writing a memory cell the voltage of the word lines is raised inducing a conducting channel between the word lines, the cut line thus runs through the induced conducting channel. A current emerging from bit line 410 and travelling through memory element 430, bottom electrode contact 440 and a N+ doped source/drain region 450 is forced to travel around the insulation grooves 4120, in order to leave the conducting channel via another source/drain region into a ground plate 4100. The ground plate is embedded in a suitable insulating material 4110 to insulate electrode contacts 440 which are penetrating the ground plate. Arrows 490 denote the curved pathway of the current in the conducting channel.

Most of the current will leave the conducting channel as denoted by arrows 490 through a ground electrode. However a small amount will travel further along the conducting channel as indicated by arrows 491, and finally leave it via memory cells located along the conducting channel, wherein the distance to the next memory cell is significantly longer than the distance in the first embodiment. Accordingly the amount of current travelling along the conducting channel is much smaller than in the first embodiment thus providing memory cells less prone to interferences when reading\writing adjacent cells.

FIG. 4C illustrates a top view on the second embodiment having a checkerboard like layout. Similar to the first embodiment the bit lines 410 are the top most elements, which cover the volumes of switching active material and their bottom contacts.

The locations of the active areas are indicated by circles 4130, which also indicate the locations of the volumes of switching active material and the vias in the ground plate below the switching active material taking the bottom electrode contacts. The perforated ground plate can thus be seen as a mesh.

From this illustration it is apparent that due to the increased distance between adjacent memory cells in either direction the amount of current running as a parasitic current through adjacent memory cells is reduced when compared to the layout of the first embodiment, thus providing less interference prone cells.

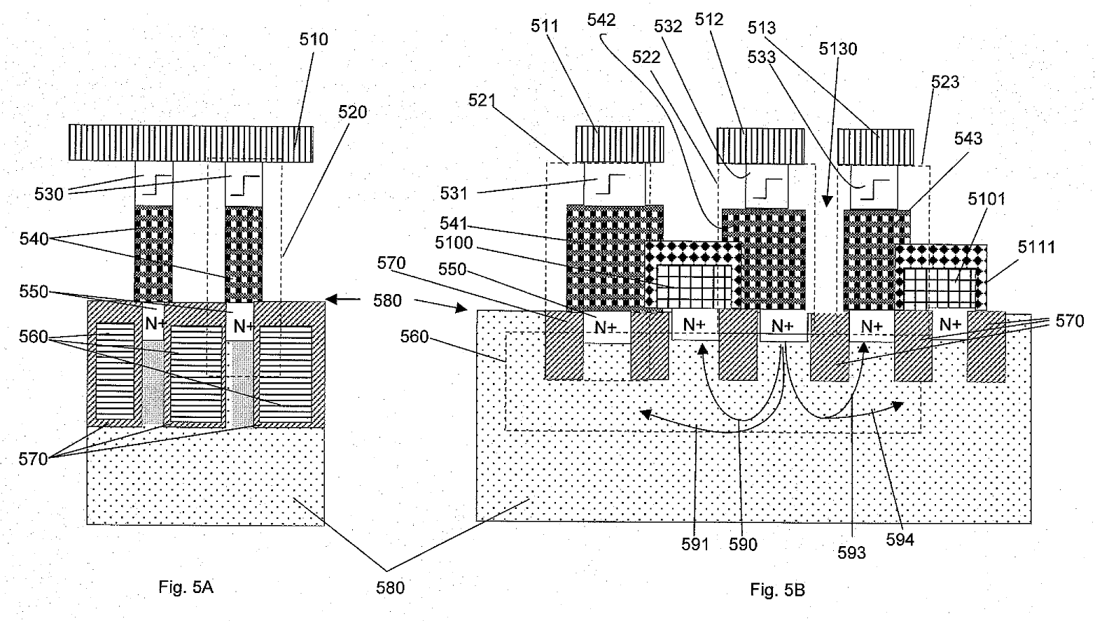

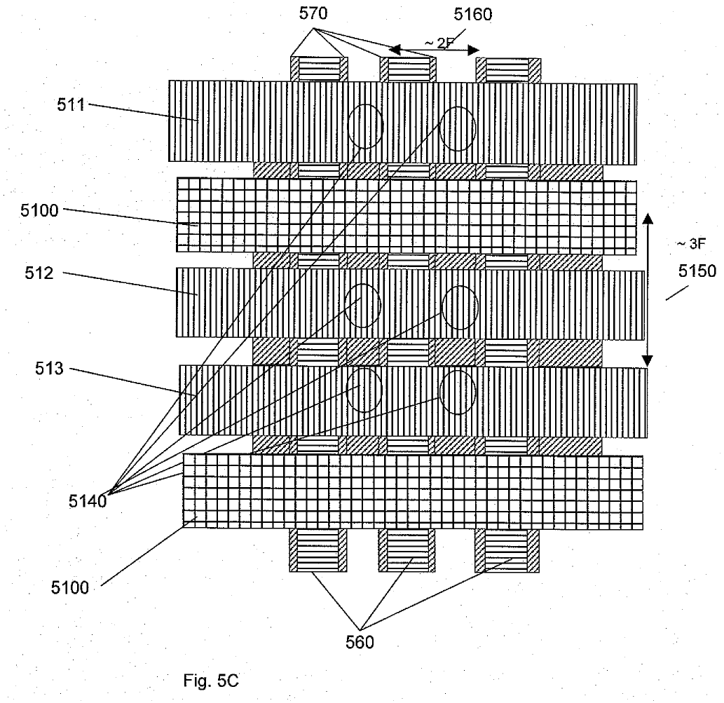

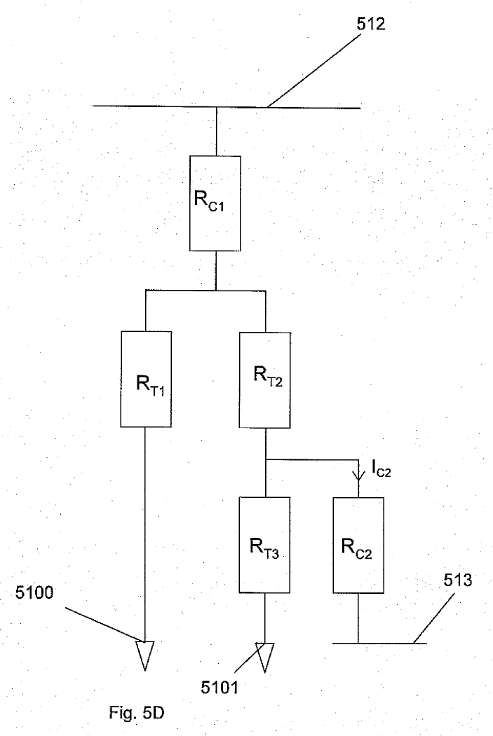

FIG. 5A illustrates a cross section of a third embodiment, wherein the cut line runs along and through a bit line 510. Similar to the afore described embodiments memory cells, which are encircled by dotted squares 520, comprise a volume of switching active material 530 as memory element, which is coupled with its top side to bit line 510 and with its bottom to a bottom electrode contact 540, which in turn is coupled to a N+ doped source/drain region 550. Word lines 560 are embedded in an insulating material, which at the same time forms the gate oxide. In this view word lines run into the paper plane, so that a conducting channel induced by a raised voltage of two adjacent word lines also runs into the paper plane, wherein the conducting channel runs between and all along the word lines. As before the word lines 560 can be formed as buried wordlines below the original surface 581 of the original wafer/substrate 580 or can be formed as a conventional word line stack—not illustrated—which is at least partially located above the surface 581 of the original substrate.

FIG. 5B illustrates a cross section of the third embodiment having a cut line perpendicular to bit lines 5 10. The illustrated memory cells exemplify a plurality of identical memory cells arranged in the illustrated layout.

The illustrated three cells are arranged as encircled by the dotted squares 521, 522 and 523. Each cell is coupled to one bit line, i.e. cell 521 is coupled to bit line 511, cell 522 couples to 512 and cell 523 couples to 513 respectively.

As illustrated there is a ground line 5100, which is covered by a suitable insulating material 5110, such as for example SiN. The ground line is placed between cells 511 and 512, whereas between cells 512 and 513 there is no ground line. Of course the memory cells are electrically isolated against each other by some interlevel dielectric in space 5130, but the memory cells 522, 523 are arranged more closely adjacent to each other, thus saving some space on the chip. Thus in this layout there is a ground line arranged between every second bit line. Further insulation grooves 5120 are arranged between adjacent source/drain regions to prevent shorts.

When operating, i.e. reading or writing, for example cell 522 the voltage of corresponding word lines, which in this view are placed in front of and behind the paper plane of the drawing and as denoted by reference numeral 560, is raised. A conducting channel is induced between the pair of word lines and extending along the word lines. Furthermore the voltage of bit line 512 is raised. A current emerging from bit line 512 will flow through memory element/switching active material 532, bottom electrode 542 and then enter the conducting channel via the source/drain element below bottom electrode 542. As the conducting channel between word lines 560 extends along the word lines the current will split up into a first portion flowing in one direction of the conducting channel and a second portion flowing in the opposite direction of the conducting channel, wherein the amplitudes of the first and second portion conversely correspond the resistance a portion sees in its flowing direction. In this way a first portion of the current will flow to the left hand side as denoted by arrows 590, 591. Most of the current will leave the conducting channel via ground line 5100, which is the closest exit from the conducting channel. However a smaller amplitude of the current will travel further along the conducting channel as indicated by 591 and will split up into several further portions, which will then leave the conducting channel through memory cells as a parasitic current or through farther ground lines.

The portion of the current flowing to the right hand direction as denoted by arrows 593, 594 will split up according to the resistance of the lineage ahead. Hence a first portion 593 will leave the conducting channel through memory cell 523, which will be comparatively small as the resistance of cell 523 will be high when compared to resistance ahead in the conducting channel. In this way adjacent memory cells serve as current drains in addition to the ground lines.

A major portion of current 594 will exit the channel through ground line 5111. However, similar as explicated afore current 594 will further split up according to the resistance ahead in the pathway and as explained later on.

FIG. 5C illustrates a top view on this layout. Bit lines 511, 512 and 513 are the topmost elements, which cover and thus hide the memory elements/volumes of switching active material and the corresponding active areas of selection transistors as indicated by circles 5140. Word lines 560, which at the same time form the gate electrodes, are embedded in insulating material 570, which also forms the gate oxide, and are the lowermost elements, thus covered by other elements. Ground lines 5100 are arranged below the bit lines and above the word lines.

Although the figure is not drawn to scale the dimensions of the layout are given by 5150 and 5160, wherein 5150 denotes the ground line pitch and 5160 denotes the word line pitch. The area of a memory cell in this layout can thus be reduced to 6 F².

In this layout ground lines 5100 are parallel to bit lines 511, 512, 513, wherein a ground line follows after two bit lines.

In FIG. 5D the resistances seen from bit line 512 and through memory cell 522 of this embodiment are illustrated. The memory element/volume of switching active material 532 is coupled to bit line 512, wherein the memory element/switching active material has a resistance value of R_{Cell1} represented by resistor R_{C1}. The resistance of bottom electrode 541 is neglected. Resistor R_{C1} is coupled to resistors R_{T1} and R_{T2} representing the resistance values of the first and second transistors. The first transistor can be considered to comprise the conducting channel to the left hand side, which in FIG. 5C is coupled to ground line 5100. In order to simplify the circuit further resistances in this direction of the current pathway are neglected.

The second transistor having a resistance of R_{T2} can be considered to comprise the conducting channel to the right hand side, which is coupled to memory cell 523 having memory element/volume of switching active material 533 having a resistance of R_{C2}. Resistor R_{T3} exemplifies the resistance of the conducting channel to ground line 5101. For simplification it is again assumed, that there will be no further current split once the ground line 5101 is reached.

For calculating the parasitic current flowing through memory cell 523 it is assumed that its memory element/volume of switching active material 533 has a low resistance value of R_{C2}=R_{T1}=R_{T2}=R_{T3}. Furthermore the potential of bit line 513 shall be equal to the potential of the ground line.

The parasitic current I_{C2} flowing through cell 523 can thus be calculated to be ⅙ of the current flowing through cell 522. This current can be reduced for example by increasing the resistivity of cell 523. Alternatively the resistivity of a conducting channel R_{T} can be decreased. As the conductivity of a conducting channel in a transistor depends from its width, the depth of the wordlines can be increased thus producing a conducting channel of increased depth.

Another alternative for reducing the parasitic current I_{C2} is to increase the voltage of bit line 513, wherein the applied voltage to cell 523 is chosen to minimize the parasitic current. This can be achieved for example by a floating potential of bit line 513, such that any current flowing through cell 523 raises the voltage of bit line 513. Alternatively a voltage can be applied to bit line 513, wherein the voltage must not exceed a threshold for writing/resetting the cell.

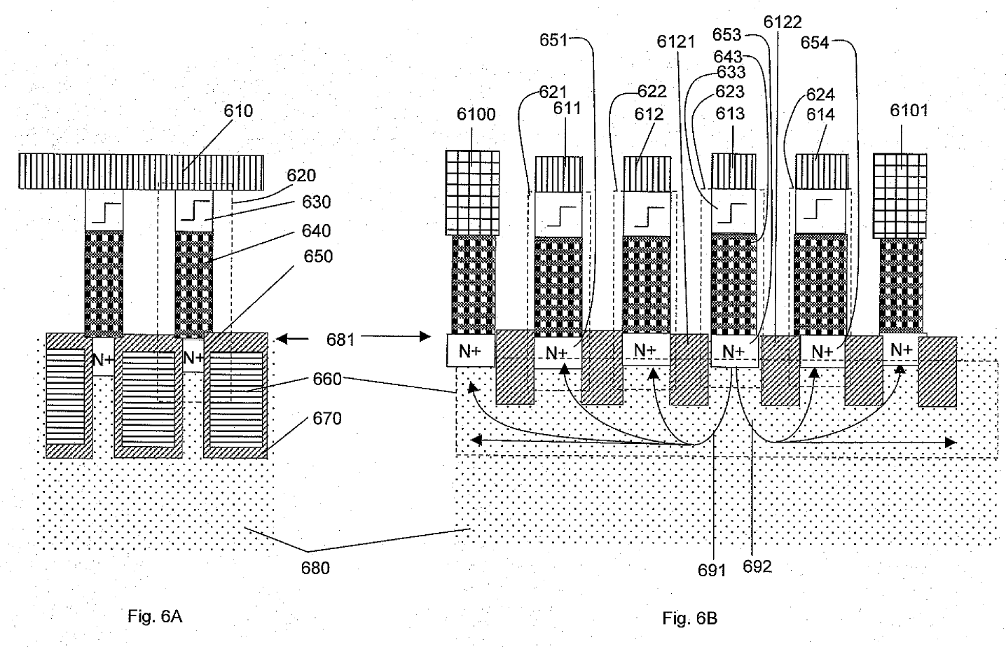

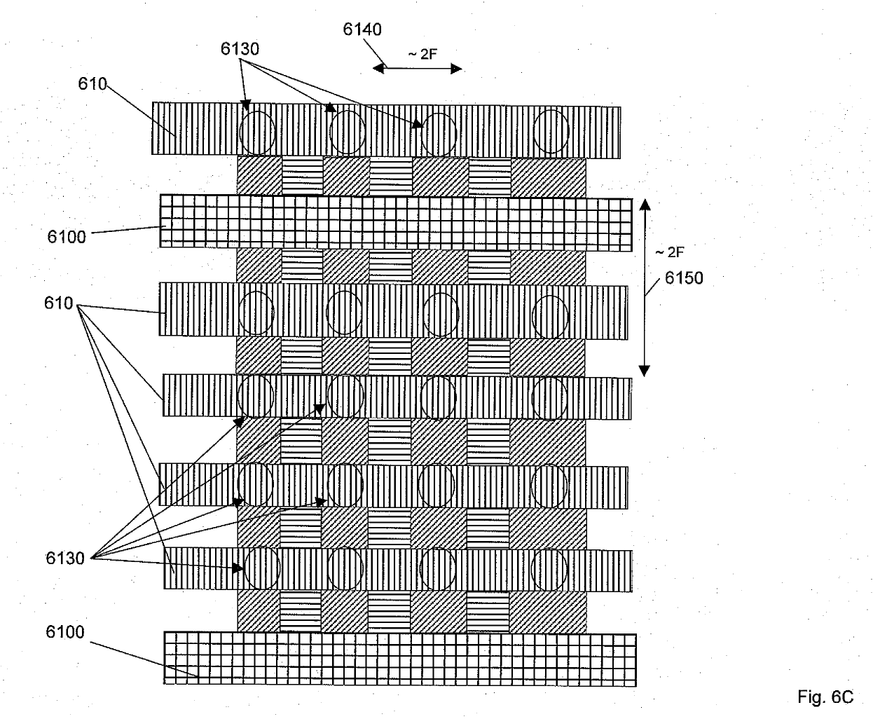

FIGS. 6A, 6B and 6C illustrate a fourth embodiment reflecting the idea of the previous embodiment more generalized.

FIG. 6A illustrates a cross sectional view through the embodiment, wherein the cut line is parallel and through a bit line 610, through two memory cells. In this view the cells have much in common with previous embodiments. An exemplifying cell 620 includes a memory element 630 coupled to a bottom electrode contact 640, which in turn couples to a source/drain region 650. Word lines 660 embedded in insulating material 670 are placed in the substrate material 680, wherein the word lines 660 are placed below the surface of the original substrate as indicated by 681.

FIG. 6B illustrates a cross sectional view through the fourth embodiment, wherein the cut line runs perpendicular to the bitlines 611 to 614. Memory cells 621 to 624 are coupled to the bitlines 611 to 614. On the left hand side of cell 621 and also on the right hand side of cell 624 there ground lines 6100, 6101 are located with four memory cells located between them. It is apparent to those skilled in the art that this layout as illustrated can modified such that three or four and more than four cells are placed between two ground lines.

The reading and writing of a memory cell will be described with cell 623. Similar to the operation explicated above the voltage of two word lines 660 is raised to induce a conducting channel and thus opening the selection transistor of the cell. In this view the word lines 660 are placed in front of and behind the paper plane as indicated by the dotted square, the conducting channel thus running horizontally in this view. Also the voltage of bit line 613 is raised causing a current to flow through memory element 633 and bottom electrode 643, which enters the conducting channel via source/drain region 653.

As indicated by arrows 691 and 692 the current entering the conducting channel will split up into two major portions, wherein a first portion 691 will pass insulation groove 6121 and then enter a first direction and a second portion will pass insulation groove 6122 and take the opposite direction. The ratio of the portions is reciprocal to the resistance the current sees when leaving source/drain region 653. Furthermore the two major portions will further split up each into several portions according to the resistances ahead in the pathway of a portion. For example portion 691 will split up into portions leaving the conducting channel through memory cells 621, 622 and a portion exiting through ground line 6100. Lastly a nearly negligible portion will pass ground line 6100 and further travel along the conducting channel, which extends all along the word lines. Similarly current portion 692 will split up into several portions according to the resistances ahead in its pathway, which will exit the conducting channel through adjacent memory cell 624 and ground line 6101 and to a nearly negligible amount through further distant memory cells and ground lines. Hence the current flowing through memory cell 623 upon operation will not only exit the conducting channel via ground lines 6100, 6101, but also through adjacent memory cells.

The amplitude of a current portion flowing through a memory cell upon reading or writing a cell sharing the same pair of wordlines as transistor gates depends on whether the operation is a read (small current) or write operation (high current), how many other cells are placed between this and the operated cell and which state, i.e. either high or low resistance, they actually have, how many ground lines are placed in the pathway between the operated cell and this cell, and the state of this memory cell itself. Furthermore the resistance of the pathway seen from the operated cell in the opposite direction influences the parasitic current.

FIG. 6C illustrates a top view on a layout according to this fourth embodiment. Similar to the afore described embodiments bit lines 610 are the top most elements covering and thus hiding in this view the active areas of the selection transistors and the memory elements/volumes of switching active material. Circles 6130 indicate the locations of the memory elements and active areas. Ground lines 6100 are parallel to bit lines 610 and are arranged after every fourth bit line.

Due to the few ground lines spread in the array of memory cells the average area needed for one cell can be reduced. Although not drawn to scale arrows 6140, 6150 illustrate the dimensions of this layout. In a layout wherein the width of a ground line is W_{wordline} and wherein n bit lines can be assigned to one ground line, the area a needed for one memory cell is given by

$$a = 2 F \times ( 2 F + \frac{1}{n} \times {W}_{wordline} )$$

If we assume for the fourth embodiment the width of a ground line to be equal to the width of a bit line and furthermore a ratio of four bit lines per ground line, then the cell size can be estimated to be

$$a = 2 F \times ( 2 F + \frac{1}{4} \times 2 F ) = 5 {F}^{2} .$$

The cell size can be further decreased by increasing the ration of bit lines to ground lines, so that the cell size can be further reduced to a=(4+x)F².

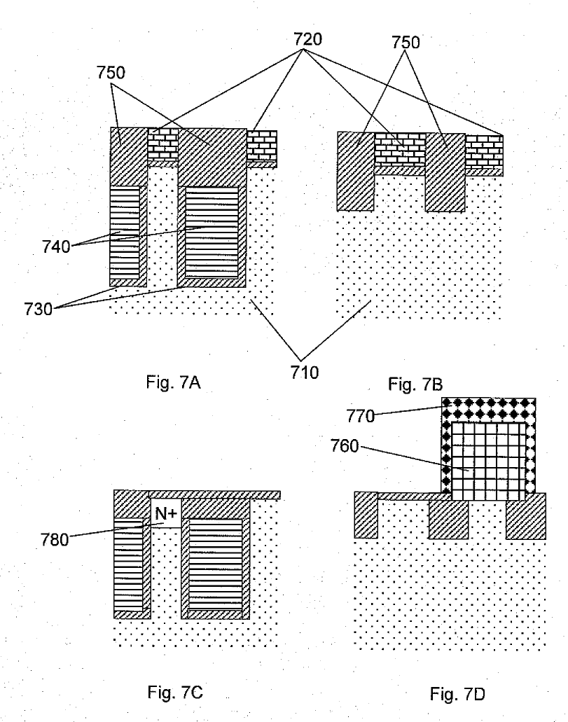

In the following the process sequence for manufacturing an array of memory cells will be described with FIGS. 7A to 7D.

FIG. 7A illustrates a cross sectional view—as in previous A figures—parallel to a bit line, which will be formed in later processes, while FIG. 7B illustrates a cross section wherein the cut line is perpendicular to that of the A figures.

The fabrication begins with performing well implants and source/drain implants by using conventional production methods in order to dope specific areas of the substrate 710. For example a p-doped surface layer and the N+ doped source/drain regions for the selection transistors are thus produced, wherein source/drain regions couple to the p-doped surface layer which provides for the conducting channels of selection transistors. Subsequently a stack of a sacrificial pad oxide and nitride layer 720 and optionally a hardmask layer are then deposited, which serve as auxiliary means in later processes.

Then grooves shaped as lines will be produced using conventional lithographic and etching processing, which are then filled with an insulator, thus forming insulation grooves 730. The insulation grooves are placed between the source/drain regions in order to separate this and to prevent shorts between them. The formation of the insulation grooves optionally may be combined with forming a shallow trench insulation for the peripheral devices.

Next word line trenches shaped as stripes are produced using conventional lithographic and etching method processes for etching the SiO of the STI and the silicon of the substrate, wherein the word line trenches may be designed for different word lines architectures. Optionally the resulting, vertical sidewalls of Si can be thinned thus widening the trenches and an array sacrificial oxidation can be performed.

Then the sacrificial oxide is stripped of and the surface in the trenches is oxidized thus forming a liner of silicon oxide serving as a gate oxide 730.

Next the word lines are formed, wherein different architectures can be used.

For example a first architecture of a word line can comprise a conventional word line stack—not illustrated—which is at least partially located above the surface plane—denoted by arrow 740—of the original substrate. The word line stack may comprise a layer of polysilicon as gate electrode topped by a layer of metal or polycide and covered by an insulating material for example such as SiN.

Alternatively the word lines can be formed as spacer word lines—not illustrated—, such that one word line trench takes two word lines located at opposite sidewalls of the word line trench. These spacer word lines can be formed by depositing a layer of conducting material and a subsequent anisotropic etching, which substantially removes the material from horizontal surfaces leaving the conducting material at vertical surfaces thus forming two spacer word lines in one trench. These spacer word lines provide the advantage that a pair of word lines being adjacent word lines in two adjacent word line trenches can be raised while at the same time the remaining word lines in these trenches can be biased negative thus limiting the conducting channel. Disadvantages of spacer shaped word lines are the extended width of the trench needed for forming the spacers and insulating the two spacer wordlines from each other and accordingly the increased effort and costs.

Another alternative is to fill the word line trenches with a conducting material thus forming one word line 740 buried below the original surface of the substrate as illustrated in the above described embodiments. The filling of the word line trenches can be accomplished using conventional processing, which can for example comprise the deposition of a suitable conducting material and a subsequent chemical-mechanical polishing (CMP) processing to planarize the word line 740 to the pad nitride.

Then the word line is recessed, for example by a conventional recess etching, and an oxide cap 750 is formed to insulate the top of the word lines 740. FIGS. 7A, 7B illustrate a manufacturing stage after performing the previous method processes.

As illustrated in FIGS. 7C and 7D, the pad nitride 720 is removed by conventional processes, for example by etching and/or CMP. Optionally well implants can then be performed for adjusting semiconductor transitions using conventional processes.

In order to form ground lines 760 the contacts are opened by etching the pad oxide thus baring the silicon of the original substrate. Ground lines 760 are then formed by deposition of a layer of suitable ground line material and subsequent patterning the layer into lines. Suitable ground line materials are metals or their polycides or a stack containing polysilicon and metal/polycides. Then a layer of insulating material to electrically insulate the ground lines is deposited, wherein for insulation of the sidewalls of the ground lines spacers are formed, such that all open sides are covered by an insulating material 770, which for example can be SiN.

Note that at least one material from the ground line stack may be shared with the gate stack used for forming the transistors for the periphery logic circuitry of the memory array.

Next well and source/drain implants can be performed to tune the semiconductor transitions. For example the source/drain regions 770 located between word lines and which will couple to a bottom electrode contact can be N+ doped.

FIGS. 7C and 7D illustrate a processing stage after having performed the above described method processes.

The pad oxide covering the source/drain regions will then be removed to open the drain contacts 770. An optional epitaxial overgrowth can be performed to increase the contact area above the source/drain regions.

In a next process an interlevel dielectric can be deposited on the surface of the chip serving as insulation between adjacent elements and also as an auxiliary means forming the memory element, i.e. the volume of switching active material. The interlevel dielectric, for example SiO, is then planarized.

In subsequent conventional processes a bottom electrode is formed on top of the recently created source/drain region, on which a volume of switching active material is deposited. Lastly bit lines will be formed, which couple to the top of the volumes of switching active material.

The proposed concept thus allows the fabrication of low cost, high density memory arrays with fully depleted, double gate selection transistors having a curved channel, wherein the transistor bodies are coupled to the substrate and wherein the ground lines are running above the surface of the original substrate. A cell can be selected by choosing the associated pair of buried word lines and the associated bit line. A leakage current may flow through non-selected close-by memory cells, which in this way serve as additional ground lines discharging the current originating from the selected/operated cell.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
an array of selection transistors formed in a substrate for selecting one of a plurality of resistively switching memory cells by selecting a pair of adjacent word lines and a bit line, and wherein a plane parallel to original surface of the substrate defines a horizontal reference plane;
a plurality of parallel word lines extending below the reference plane in a first horizontal direction, a pair of adjacent word lines serving as gate electrodes of at least one selection transistor;
at least one ground line arranged above the reference plane and parallel to the bit lines; and
a plurality of insulation grooves and source/drain regions alternately arranged between the pairs of word lines, wherein the source/drain regions couple to volumes of switching active material in the memory cells or to the at least one ground line.

2. The integrated circuit of claim 1, comprising wherein in the order of bit lines and parallel ground lines at least two bit lines are arranged between two adjacent ground lines.

3. The integrated circuit of claim 1, comprising wherein bit lines and parallel ground lines are arranged alternating.

4. The integrated circuit of claim 1, comprising wherein a depth of the word line trenches vertically exceed a depth of the insulation grooves.

5. The integrated circuit of claim 1, comprising wherein in a word line trench the thickness of an insulating layer arranged at the bottom considerably exceeds the thickness of the gate oxide arranged at the sidewalls.

6. The integrated circuit of claim 1, comprising wherein the thickness of the gate oxide arranged at the bottom exceeds the thickness of the gate oxide arranged at the sidewalls by at least a factor of two.

7. The integrated circuit of claim 1, comprising wherein the ground lines vertically extend to the level of the bit lines.

8. The integrated circuit of claim 1, comprising wherein a word line trench takes one word line.

9. The integrated circuit of claim 8, comprising wherein the word line is shared by a first and a second pair of word lines.

10. The integrated circuit of claim 8, comprising wherein the memory cells are arranged checkerboard like at the intersections of pairs of word lines and bit lines.

11. The integrated circuit of claim 1, comprising wherein a word line trench takes a first and a second word line.

12. The integrated circuit of claim 11, comprising wherein the word lines are formed as spacer word lines.

13. The integrated circuit of claim 1, comprising wherein a word line is formed by a stack of at least a poly silicon and a metal.

14. The integrated circuit of claim 13, comprising wherein the word line stack is at least partially arranged above the reference plane.

15. The integrated circuit of claim 14, comprising wherein the metal is arranged above the reference plane.

16. The integrated circuit of claim 1, comprising wherein ground lines are situated below bit lines.

17. The integrated circuit of claim 10, comprising wherein the ground line is a plate or mesh.

18. A method of operating an integrated circuit including one of an array of selectively switching memory cells comprising:
selecting a corresponding dual gate selection transistor formed in a substrate and a corresponding perpendicular bit line;
raising the voltage of a bit line, and
raising the voltage of a pair of word lines thus causing a current flowing through a switching active material and a conducting channel induced between the word lines and leaving the conducting channel via at least one ground line.

19. The method of claim 18 comprising:
wherein a plane parallel to the original surface of the substrate defines a horizontal reference plane;
wherein the gate electrodes of the selection transistor are formed by a pair of adjacent word lines running in a first horizontal direction and being at least partially arranged below the reference plane, and
wherein source/drain regions and insulation grooves extending from the reference plane into the substrate are arranged alternating between the pair of word lines, the source/drain regions coupling to volumes of switching active material of the cells and to a ground line respectively, and
wherein the ground line is arranged parallel to the bit line and above the reference plane.

20. The method of claim 18, comprising wherein the operated cell and at least one other, non-operated memory cell share the same pair of word lines and are arranged between two adjacent ground lines, and wherein the current flowing through the operated cell partially discharges through the other non-operated cell.

21. The method of claim 18, comprising wherein the operated cell and at least one additional non-operated memory cell share the same pair of word lines and are arranged between two adjacent ground lines, and
raising the voltage of the bit line coupled to the non-operated cell in order to lower a discharge current through the non-operated cell.

22. The method of claim 18, comprising wherein the operated cell and at least one additional non-operated memory cell share the same pair of word lines and are arranged between two adjacent ground lines, and keeping the bit line coupled to the non-operated cell floating in order to lower the amount of discharge current through the non-operated cell.

23. The method of claim 18, comprising wherein one word line trench takes one word line and wherein a second pair of word lines shares one word line with the first pair of word lines, and biasing the second word line of the second pair negatively for lowering the conductance between the second pair of word lines.

24. The method of claim 18, comprising forming a word line from only polysilicon or a metal or both.

25. The method of claim 18, comprising forming wherein a word line as a stack comprising at least a layer of poly silicon and a layer of metal.

26. The method of claim 18, comprising wherein a one word line trench takes a first and a second word line, the first wordline belonging to the pair of wordlines of the operated cell, wherein the second wordline is biased negatively.

27. A method of fabricating an integrated circuit comprising an array of selection transistors for selecting one of an array of resistively switching memory cells in a substrate, and wherein a plane parallel to the original surface of the substrate defines a reference plane, comprising:
performing well implants and source drain implants for producing a P-doped surface layer in the substrate comprising N-doped source/drain areas;
depositing a pad layer of silicon oxide and subsequently a pad layer of silicon nitride on the substrate;
forming a plurality of parallel insulation grooves in the substrate and in the form of stripes running in a first horizontal direction, the insulation grooves filled with an insulating material;
forming a plurality of word lines running perpendicular to the insulation grooves by forming word line trenches, producing a layer of insulating material in the word line trenches, depositing a conducting word line material in the word line trenches, recessing the word line material and forming an insulating cap covering the word lines;
forming ground lines running perpendicular to the word lines and above the reference plane by locally removing at least one pad layer and depositing a ground line layer, such that the ground lines are coupled to source/drain regions, and subsequently patterning the ground line stack and forming an insulating cover on the ground line stack;
forming bottom electrode contacts coupling to the residual source/drain regions;
forming volumes of switching active material on top of the bottom electrode contacts; and
forming bit lines coupling to the volumes of switching active material, the bit lines running perpendicular to the word lines.

28. The method of claim 27, comprising depositing a layer of hardmask material on the substrate.

29. The method of claim 27, comprising wherein the insulation groove material is silicon oxide.

30. The method of claim 27, comprising thinning the substrate material between adjacent word line trenches after the word line trenches have been etched.

31. The method of claim 27, comprising etching the depth of the word line trenches at least to the depths of the insulation grooves.

32. The method of claim 27, comprising achieving the production of a layer of insulating material in the word line trenches by oxidizing the substrate material in the word line trenches.

33. The method of claim 27, comprising producing two spacer word lines in one word line.

34. The method of claim 27, wherein forming the ground lines comprises the formation of insulating spacers to cover the sidewalls of a ground line.

35. The method of claim 27, wherein forming of bottom electrode contacts comprises to locally strip a pad layer above source/drain contacts and performing an epitaxial overgrowth to enlarge the contact area of the bottom electrode contacts.

36. The method of claim 27, comprising shaping the ground line as a plate or a mesh.

37. An integrated circuit having a memory comprising:
an array of memory cells having dual gate transistors, configured to allow a portion of a memory cell current to flow through adjacent memory cells.

38. The integrated circuit of claim 37, comprising:
where the dual gate transistors are configured to provide a curved current flow.

39. The integrated circuit of claim 37, comprising:
wherein the memory cells are resistivity changing memory cells.

40. The integrated circuit of claim 37, comprising:
where the memory cells comprise an operated cell and at least one non-operated cell sharing a same pair of word lines, and where the current flowing through the operated cell partially discharges through the at least one non-operated cell.
